(19) United States
(12) Patent Application Publication
(10) Pub. No.: US 2024/0348220 A1
(43) Pub. Date: Oct. 17, 2024

(54) AMPLIFIER CIRCUIT WITH DYNAMIC OUTPUT SLOPE COMPENSATION FOR DRIVING LARGE CAPACITIVE LOADS

(71) Applicant: Infineon Technologies AG, Neubiberg (DE)

(72) Inventors: Cristian Murtaza, Bucharest (RO); Florin Biziitu, Bucharest (RO)

(21) Appl. No.: 18/598,692

(22) Filed: Mar. 7, 2024

(30) Foreign Application Priority Data
Apr. 13, 2023 (DE) 102023109283.9

(51) Int. Cl. H03F 3/45

(52) U.S. Cl. CPC H03F 3/45748; H03F 3/4521; H03F 3/45273; H03F 2200/462

(57) ABSTRACT

An amplifier circuit is described herein. In accordance with one embodiment, the circuit includes an input stage and an output stage. The input stage has a non-inverting input and an inverting input for receiving a differential input voltage and is configured to provide an output signal that represents the differential input voltage. The output stage is configured to receive—as input signal—the output signal of the input stage and to provide—at an amplifier output—an output voltage based on the input signal. A feed-back path couples the amplifier output with the inverting input of the input stage. A feed-forward circuit is configured to activate a current path coupled to the amplifier output to provide additional output current when the differential input voltage crosses a threshold.

This disclosure relates to the field of amplifier circuits. In particular to a current-sense amplifier which can be operated with capacitive loads in a wide range of capacitances.

### BACKGROUND

Current sensing is required in many applications, such as, for example, motor control. It is known to integrate current sense amplifiers together with other circuitry in, for example, dedicated motor control integrated circuits (ICs) and MOSFET driver ICs, or the like. Such current sense amplifiers may be designed to amplify, for example, the voltage drop across a current sense resistor and may be optimized for both current consumption and dynamic performance (transient response time to a large input differential voltage jump).

Known current sensing approaches use either a digital approach (using analog-to-digital converters, ADCs) or an analog approach. Digital approaches often require a high-speed ADC, which significantly increases the complexity of the overall application, because it requires a carefully designed anti-aliasing filter. The digital approach also typically comes with higher quiescent current. Digital solutions are therefore not always suited for integration in small packages with limited power dissipation capabilities. Accordingly, the present disclosure is focused on analog current sensing concepts, which generally allow lower quiescent currents.

In order to satisfy requirements concerning step response/slew rate as well as the requirements concerning power dissipation (current consumption) the capacitance of the load connected to the amplifier output usually has to be within a narrow range (usually 10 pF up to 400 pF). Applications that need a larger output capacitances without increasing the quiescent current usually have to allow a longer transient response time.

The inventors have set themselves the object to improve the transient response time of amplifier circuit for large output capacitors (e.g. 2-3 nF) without increasing the quiescent current of the amplifier.

### SUMMARY

The object is achieved by the circuit of claims 1 and 10 and the method of claim 9. Various embodiments and further developments are covered by the dependent claims.

A first embodiment relates to an amplifier circuit that includes an input stage and an output stage. The input stage has a non-inverting input and an inverting input for receiving a differential input voltage and is configured to provide an output signal that represents the differential input voltage. The output stage is configured to receive—as input signal—the output signal of the input stage and to provide—at an amplifier output—an output voltage based on the input signal. A feed-back path couples the amplifier output with the inverting input of the input stage. A feed-forward circuit is configured to activate a current path coupled to the amplifier output to provide additional output current when the differential input voltage crosses a threshold.

A further embodiment relates to a method for operating an amplifier. The method includes providing—by an input stage of the amplifier—an output signal that represents a differential input voltage of the input stage. The method further includes providing—by an output stage of the amplifier—an output voltage at an amplifier output based on the output signal of the input stage, wherein a feed-back path couples the amplifier output with an inverting input of the input stage. Furthermore, the method includes activating a current path coupled to the amplifier output to provide additional output current, when the differential input voltage crosses a threshold value.

### BRIEF DESCRIPTION OF THE DRAWINGS

In the following detailed description, reference is made to the accompanying drawings. The drawings form a part of the description and, for the purpose of illustration, show examples of how the invention may be used and implemented. It is to be understood that the features of the various embodiments described herein may be combined with each other, unless specifically noted otherwise.

FIG. 1 illustrates one example of a current sense amplifier circuit.

FIG. 2 illustrates an example of an output stage which may be used in the circuit of FIG. 1.

FIG. 3 illustrates one example of an improved current sense amplifier circuit, which has an improved dynamic performance while requiring only a low quiescent current even for higher output capacitances.

FIG. 4 illustrates an alternative implementation of the embodiment of FIG. 3.

FIG. 5 illustrates the complementary circuit with respect to the circuit of FIG. 4.

### DETAILED DESCRIPTION

Analog current sensing solutions that are capable of driving high capacitive loads at low quiescent currents can be implemented using a class AB output stage in the difference amplifier which is used in the current sense amplifier circuit. However, solutions using a class AB output stage may have a reduced linearity, problems concerning the loop stability and/or a higher transient response time. Loop stability or transient response time could be affected because using a class AB output stage usually implies using a Miller compensation.

Simultaneously satisfying the requirements concerning linearity (distortion), loop stability and transient response time may therefore be a big challenge when using class AB output stages in the difference amplifier. Therefore, some embodiments described herein, use a source follower output stage. However, without further measures (which will be described later), source followers usually allow only small output capacitances. Larger output capacitances such as 2-3 nF would require an undesired (or unfeasible) increase in quiescent current.

The embodiments described herein may enable a fully integrated solution for a current sense amplifier circuit which is capable to ensure a low static (DC) current consumption while providing a fast response time to a large input differential voltage jump for a wide range of capacitive loads (e.g. 10 pF to 3 nF).

FIG. 1 illustrates, by way of example, the general structure of a current sense amplifier circuit, which is configured to amplify the voltage drop Vs across the current sense resistor R_{S} (Vs=i_{S}·R_{S}), which carries the current is to be measured. The current sense resistor R_{S} is connected between a first input node ISN and a second input node ISP of the current sense amplifier circuit.

The “core” of the current sense amplifier circuit is a differential amplifier which comprises an input stage AMP₁ and output stage AMP₂. The input stage AMP₁ has a non-inverting input (+) and an inverting input (−). These inputs are configured to receive a differential input voltage V_{P}−V_{N}, wherein V_{P} denotes the voltage at the non-inverting input and V_{N} denotes the input of the inverting input. The input stage AMP₁ is configured to provide an output signal V_{O} that represents the differential input voltage V_{P}−V_{N}. The input stage AMP1 is a differential amplifier with a high open-loop gain (e.g. greater than 90 dB). In many implementations, the input stage includes an operational transconductance amplifier (OTA). The output stage AMP₂ is configured to receive—as input signal—the output signal V_{O} of the input stage AMP₁ and to provide—at an output OUT—an output voltage VOUT based on the input signal. In most embodiments, the output voltage V_{OUT} is substantially proportional to the voltage V_{O}. The output stage AMP₂ is usually a buffer amplifier which is capable of driving capacitive loads. In most implementations, the output stage AMP₂ has a unity gain.

The inverting input of the input stage AMP₁ is connected to the first input node ISN via a first resistor R₁, and the non-inverting input is connected to the second input node ISP via a second resistor R₂. As mentioned, the current sense resistor R_{S} is connected between the nodes ISP and ISN. A feed-back path couples the output OUT of the output stage AMP₂ with the inverting input of the input stage AMP₁. In the depicted example, the feed-back path includes only a resistor R₃. The non-inverting input of the input stage AMP₁ is coupled, via resistor R₄, to a circuit node, to which a reference voltage V_{REF} is supplied. Assuming R₁=R₂=R and R₃=R₄=N. R the gain of the current sense amplifier circuit is N, i.e. V_{OUT}=N·V_{S}=i_{S}·N·R_{S}.

In the depicted example, the reference voltage is provided by an operational amplifier OA, which is configured to amplify the voltage provided at the middle tap of a voltage divider composed of resistors R₅ and R₆. The operational amplifier OA is configured as a buffer amplifier, i.e. its output is connected to its inverting input, wherein the non-inverting input is connected to the middle-tap of the mentioned voltage divider that is coupled between supply voltage V_{DD} and ground GND. In the present example, in which R₆=R and R₅=4·R, the reference voltage V_{REF} is 0.2 times the supply voltage V_{DD}, i.e. V_{REF}=0.2. V_{DD}. The capacitor C_{OUT} connected to the output OUT symbolizes the capacitive load impedance, which the current sense amplifier has to drive. It is understood that the purpose of the reference voltage V_{REF} is merely to determine the DC level of the output voltage V_{OUT} when the input voltage V_{S}=i_{S}·R_{S}=0 volts.

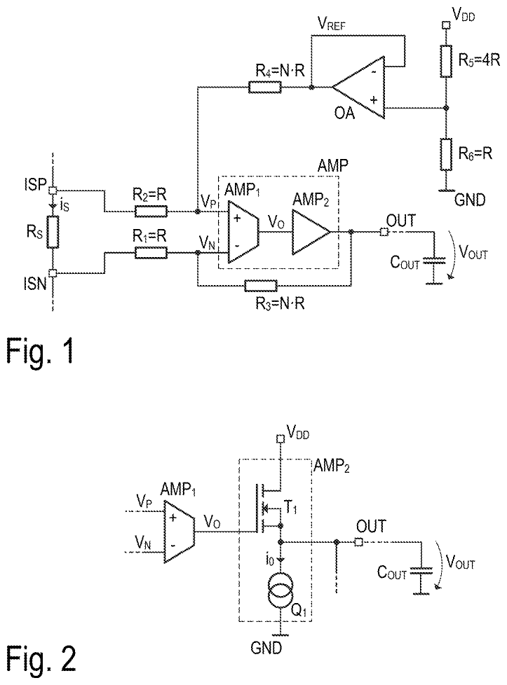

As mentioned above, the output stage AMP₂ may be implemented using a source follower in the embodiments described herein. An example is shown in FIG. 2. Accordingly, the output stage AMP₂ includes an n-channel MOS (metal-oxide-semiconductor) field-effect transistor (FET) T₁ whose drain electrode is connected to a supply node (supply voltage V_{DD})) and whose source electrode is connected to the output node OUT. The gate electrode of transistor T₁ is connected to the output of the input stage AMP₁ and receives—as input voltage—the voltage V_{O}. A current source Q₁ is connected between the output node OUT and the ground node GND. The current source Q₁ provides a bias current i₀. Various ways of implementing the current source are as such known to a skilled person and are thus not discussed herein in more detail. It is understood, that FIG. 2 shows merely an example. In other embodiments, the circuit may be “flipped”, wherein the n-channel MOSFET is replaced by a p-channel MOSFET to obtain a complementary circuit. Furthermore, it is understood that the MOSFET T₁ may be replaced by a bipolar junction transistor (npn- or pnp-type dependent on the actual implementation.

The concept described herein allows driving capacitive loads (see FIG. 2, capacitance C_{OUT}) with a low distortion output stage (such as the source follower discussed above) that does not negatively affect the linearity, loop stability and transient response time, while simultaneously keeping the power dissipation low (low quiescent current i₀).

As can be seen in FIG. 2, source follower output stages are typically asymmetric with respect to the transient response times for charging and discharging the output capacitance C_{OUT}. Depending on the implementation (i.e. dependent on whether a p-channel MOSFET or an n-channel MOSFET is used) either the transient response time for discharging or for charging the output capacitance can easily be reduced by properly sizing the MOSFET, whereas the other response time is determined by the low quiescent current i₀.

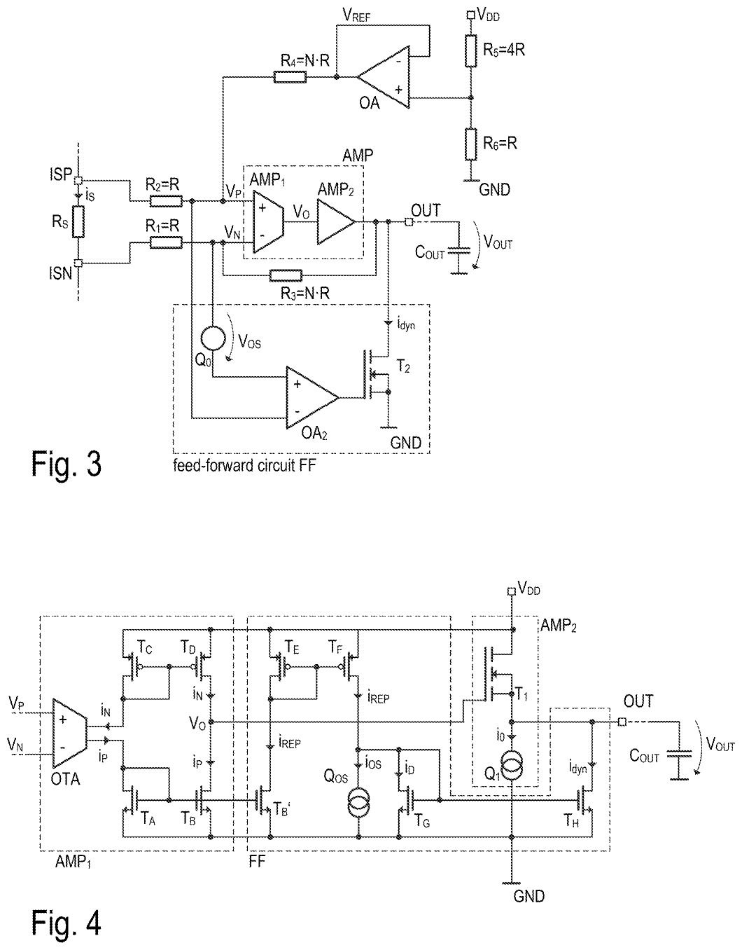

In the example of FIG. 2 (n-channel MOSFET) the transient time for discharging the output capacitance can be reduced by drastically increasing the bias current i₀, since the slew rate of the output is given by the magnitude of the (static) bias current i₀. However, a massive increase of the bias current i₀ is undesired as this would significantly increase losses. Using a class AB output stage would resolve the problem of asymmetric transient response times but deteriorate linearity for a given open loop gain (which is necessary to achieve the desired loop stability and a low offset). The example shown in FIG. 3 provides a compromise between low losses, high slew rate, and high linearity.

The example of FIG. 3 is the same as the circuit of FIG. 1 except that the amplifier circuit includes an additional feed-forward circuit FF that is configured to activate a current path coupled to the output OUT to provide additional output current i_{dyn}, when the differential input voltage V_{P}−V_{N} crosses a specific (determined by the circuit design) threshold value V_{OS}.

The current path of the feed-forward circuit FF may include a controllable current source coupled to the output of the output stage AMP2. In the depicted example, the controllable current source is implemented using an n-channel MOSFET T₂ whose drain-source current path lies between the output node OUT and ground node GND. When a sufficiently high gate voltage is applied to the gate electrode of the transistor T₂, then the transistor T₂ becomes conductive and an additional bias current i_{dyn} may flow from the output node OUT to ground (in additional to bias current i₀, see FIG. 2).

The mentioned controllable current source (e.g. the transistor T₂) is activated, when the differential input voltage V_{P}−V_{N} crosses the mentioned threshold value V_{OS}. In the depicted example, the gate voltage for transistor T₂ is provided by a differential amplifier OA₂, which may also be an operational amplifier. The amplifier OA₂ receives—as input voltage—the voltage V_{N}−V_{P}−V_{OS}, wherein the offset voltage V_{OS} is provided by a voltage source Q0 coupled between the inverting input of the input stage AMP₁ and the non-inverting input of the differential amplifier OA₂. As a consequence, the differential amplifier OA₂ generates a positive gate voltage when differential input voltage V_{P}−V_{N} falls below the (negative) threshold value−V_{OS}. It is understood that FIG. 3 is merely an example and a skilled person is able to implement basically the same function in a different way. For example, an npn-type bipolar junction transistor may be used instead of MOSFET T₂. Dependent on the implementation of the output stage AMP₂ (source follower), a complementary circuit may be used, in which n-channel transistors are replaced by p-channel transistors while the circuit is “flipped”.

The feed-forward circuit FF may be seen as an additional compensation loop, which is able to provide a current-path for a fast discharge of larger capacitive loads when negative differential transients appear at the input of the amplifier circuit. The static current consumption (and thus the losses) is not increased because the compensation loop activates the discharge current-path only temporarily while the differential input voltage V_{P}-V_{N} is sufficiently negative (or sufficiently positive if complementary implementations are used for the source follower and the controllable current source (transistor T₂)).

The concept described herein is enables keeping the DC current consumption low (low bias current i₀ in the output stage) even when using capacitive loads C_{OUT} of, e.g., 2 nF which is a typical value in motor control applications. At the same time, the concept described herein allows a fast response to large differential voltage swings at the input independent of the load capacitance C_{OUT}. A response time as low as 1 μs may be achieved for maximum loads of 2.5 nF. In contrast thereto, in conventional applications the output capacitance range is specified as 10 pF up to 400 pF. Accordingly, the embodiments presented herein may be able to drive an output capacitance more than six times higher than conventional approaches.

FIG. 4 illustrates one example of a practical implementation of the concept illustrated in FIG. 3. It is noted that only the input stage AMP₁, the output stage AMP₂ and the feed-forward circuit FF are shown in FIG. 4 to keep the illustration simple. The rest of the circuit may be implemented as shown in FIG. 3.

As shown in FIG. 4, the input stage AMP₁ includes an operational transconductance amplifier OTA with a differential current output (currents i_{P} and i_{N}). The output current i_{P} of the OTA is supplied to a first current mirror composed of the (n-type) transistors T_{A} and T_{B}. Similarly, the output current i_{N} of the OTA is supplied to a second current mirror composed of the (p-type) transistors T_{C} and T_{D}. As shown in the depicted example, the transistors T_{A}, T_{B}, T_{C}, and T_{D} may be field effect transistors. Assuming that the current mirrors have a unity gain, the current mirrors do only invert the direction of the currents without scaling. The output branches of the first and second current mirrors are connected at an output circuit node, at which the output voltage Vo of the input stage AMP₁ is provided. This output voltage V_{O} is supplied to the input of the output stage AMP₂, i.e. to the gate of transistor T₁ which is configured as source follower as explained above with reference to FIG. 2. Current source Q₁ provides the static bias current for the transistor T₁. Reference is made to the description of FIG. 2 to avoid unnecessary reiterations.

As explained above, the additional current path (for the current i_{dyn}) in the feed-forward circuit is activated when differential input voltage V_{P}−V_{N} of the input stage AMP₁ falls below the (negative) threshold value −V_{OS}. In the previous example of FIG. 3, the condition V_{P}−V_{N}<−V_{OS} is directly evaluated by the differential amplifier OA₂ (and using the offset voltage source Q₀). FIG. 4 illustrates an alternative approach for evaluating the condition V_{P}−V_{N}<−V_{OS}. For this purpose, a replica of the current i_{P} is generated by adding an additional output branch (transistor T_{B}′) to the first current mirror. As can be seen from FIG. 4, the output current i_{P} of the OTA in the input stage AMP₁ is drained via transistor T_{A} which forms the input branch of the first current mirror. The current i_{P} is “copied” to the output branch formed by transistor T_{B}′ and an additional replica current i_{REP}=i_{P} flows through transistor T_{B}′. The source electrode of transistor T_{B}′ is coupled to ground GND, while the drain electrode of transistor T_{B}′ is coupled to the input branch of a third current mirror composed of (p-type) transistors T_{E} and T_{F}. The replica current i_{REP}=i_{P} is then again “copied” by the third (e.g. unity gain) current mirror. The concept of current mirrors with multiple output branches is well known and thus not further discussed herein.

The offset voltage V_{OS} is represented by an equivalent offset current i_{OS}, which is provided by current source Q_{OS}. The current source Q_{OS} is connected between a ground node (GND) and the drain electrode of transistor T_{F}. That is, the current source Q_{OS} is coupled to the output branch of the third current mirror (transistors T_{E} and T_{F}). The offset current i_{OS} is determined by circuit design and is usually constant. The replica current i_{REP}=i_{P} is determined by the output current i_{P} of the OTA. As a consequence the difference current i_{D}=i_{REP}-i_{OS} has to be drained from the circuit node at which the current source Q_{OS} and transistor T_{F} are connected. In the present example, this difference current is drained (to ground) via the input branch of a fourth current mirror that is composed of transistor T_{G} (input branch) and transistor T_{H} (output branch). This current mirror may be configured to amplify the current i_{D} in the input branch. Accordingly, the current i_{dyn} in the output branch of the third current mirror may be proportional to current i_{D} (i.e. i_{dyn}=K·i_{D}, proportionality factor K). The transistor T_{H} in the output branch of the third current mirror has the same function as transistor T₂ in the previous example of FIG. 3.

When comparing the circuits of FIGS. 3 and 4, one can see that, in the example of FIG. 4, only four transistors, namely T_{B}′, T_{E}, T_{F} and T_{G}, are needed instead of the differential amplifier OA₂ while an offset current source Q_{OS} is used instead of the offset voltage source Q₀. The transistor TH may be seen as a controllable current source because the current i_{dyn} passing through the transistor T_{F} is controlled by the current difference i_{D}. As the output current i_{P} of the OTA is inversely proportional to the differential input voltage V_{P}−V_{N}, the difference current i_{D}=i_{P}-i_{OS} (assuming i_{REP}=i_{P}) is indicative of the voltage V_{N}−V_{P}−V_{OS}, which, in FIG. 3, is the differential input of the differential amplifier OA₂. The third current mirror (transistors T_{E} and T_{F}) amplify the current i_{D} to obtain the current i_{dyn} and thus has basically the same function has the differential amplifier OA₂ in FIG. 3. Accordingly, the feed-forward circuit in the example of FIG. 4 is equivalent to the feed-forward circuit of FIG. 3, wherein, however, the example of FIG. 4 is simpler to implement.

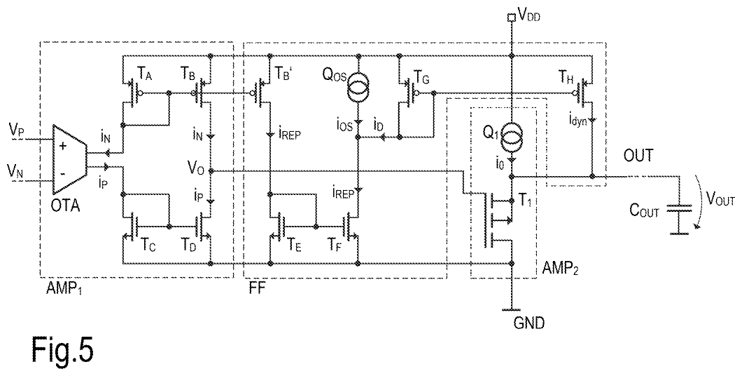

It is again, emphasized that the circuit of FIG. 4 can be transformed in a complementary circuit, in which the n-type transistors and p-type transistors change roles. For example, in such a complementary circuit, the transistor T_{H} would be a p-type transistor coupled between the output OUT and the supply node (voltage V_{DD}). An example is illustrated in FIG. 5. The function is substantially the same as the function of the circuit of FIG. 4 and reference is made to the respective explanations above. Figuratively speaking, the circuit of FIG. 5 is “flipped” upside down as compared to the circuit of FIG. 4, wherein each p-type transistor is replaced by a complementary n-type transistor and vice versa. Further, in FIG. 5, the replica current i_{REP} provided by transistor T_{B}′ is a replica of the output current iₙ of the OTA. The difference current i_{P} is therefore i_{REP}−i_{OS}=i_{N}−i_{OS} (in case the current mirror composed of transistors T_{A} and T_{B}′ has unity gain).

In the example of FIG. 4, as long as the magnitude of differential input voltage V_{P}−V_{N} is lower than the offset voltage, the feed-forward circuit has substantially no effect. The DC current consumption of the output stage AMP₂ is low and determined by the bias current source Q₁ (see FIGS. 2 and 4). Only when the differential input voltage V_{P}−V_{N} falls below the offset−V_{OS} (or, in case of the complementary circuit, exceeds the offset V_{OS}) the feed-forward circuit becomes active and provides a current path (e.g. transistor T₂ or T_{H}, see FIGS. 3, 4 and 5) for quickly discharging (or, in case of the complementary circuit, for quickly charging) the output capacitance C_{OUT}.

Various embodiments described herein are summarized below. It is understood that the following is not an exhaustive list but rather an exemplary summary. A first embodiment relates to an amplifier circuit that includes an input stage and an output stage (see FIGS. 3 and 4, AMP₁ and AMP₂). The input stage has a non-inverting input (+) and an inverting input (−) for receiving a differential input voltage (see FIGS. 3 and 4, voltage V_{P}−V_{N}) and is configured to provide an output signal that represents the differential input voltage. The output stage is configured to receive—as input signal—the output signal of the input stage and to provide—at an amplifier output—an output voltage based on the input signal. A feed-back path couples the amplifier output with the inverting input of the input stage. In a simple embodiment, the feed-back path basically consists of a resistor (see FIG. 3, feed-back resistor R₃). A feed-forward circuit is configured to activate a current path coupled to the amplifier output to provide additional output current (see FIGS. 3 and 4. current i_{dyn}) when the differential input voltage crosses (e.g. exceeds or falls below, dependent on the actual implementation) a threshold value (see FIGS. 3 and 4. offset voltage V_{OS} and, respectively, offset current i_{OS}).

One embodiment specifically relates to a current sensing application. In such an embodiment, a current sense resistor is connected between a first input node and a second input node (see FIG. 3, ISN and ISP) The inverting input of the input stage is connected to the first input node via a first resistor and the non-inverting input of the input stage is connected to the second input node via a second resistor. The non-inverting input is connected to a reference voltage source via another resistor (see FIG. 3, reference voltage V_{REF}).

The current path of the feed-forward circuit may include a controllable current source coupled to the amplifier output, wherein the controllable current source is activated when the differential input voltage crosses the mentioned threshold value (e.g. determined by V_{OS} or i_{OS}, see FIGS. 3 and 4).

The output stage may include a source follower (see FIG. 2), which provides high linearity and loop-stability. The source follower may be composed of an n-channel field effect transistor, while the feed-forward circuit is configured to sink the additional output current, when the differential input voltage falls below the threshold value (see FIGS. 3 and 4). As mentioned above, the embodiments shown in the Figures may readily be transformed into complementary circuits. In these embodiments the source follower is composed of a p-channel field effect transistor, wherein the feed-forward circuit is configured to source the additional output current when the differential input voltage exceeds the threshold value.

A further embodiment relates to a method for operating an amplifier. The method includes providing—by an input stage of the amplifier—an output signal that represents a differential input voltage of the input stage. The method further includes providing—by an output stage of the amplifier—an output voltage at an amplifier output based on the output signal of the input stage, wherein a feed-back path couples the amplifier output with an inverting input of the input stage. Furthermore, the method includes activating a current path coupled to the amplifier output to provide additional output current, when the differential input voltage crosses a threshold value.

Although the invention has been illustrated and described with respect to one or more implementations, alterations and/or modifications may be made to the illustrated examples without departing from the spirit and scope of the appended claims. In particular regard to the various functions performed by the above described components or structures (units, assemblies, devices, circuits, systems, etc.), the terms (including a reference to a “means”) used to describe such components are intended to correspond—unless otherwise indicated—to any component or structure, which performs the specified function of the described component (e.g., that is functionally equivalent), even though not structurally equivalent to the disclosed structure, which performs the function in the herein illustrated exemplary implementations of the invention.

1. An amplifier circuit comprising:
an input stage including a non-inverting input and an inverting input for receiving a differential input voltage, the input stage being configured to provide an output signal that represents the differential input voltage;
an output stage configured to receive, as an input signal, the output signal of the input stage and further configured to provide, at an output, an output voltage based on the input signal;
a feed-back path that couples the output of the output stage with the inverting input of the input stage; and
a feed-forward circuit is configured to activate a current path coupled to the output to provide an additional output current when the differential input voltage crosses a threshold value.

2. The amplifier circuit of claim 1,
wherein the inverting input is connected to a first input node via a first resistor and the non-inverting input is connected to a second input node via a second resistor, and
wherein the second input node and the first input node are connected by a current sense resistor.

3. The amplifier circuit of claim 2,
wherein the feed-back path includes a third resistor.

4. The amplifier circuit of claim 3,
wherein the non-inverting input is connected to a reference voltage source via a fourth resistor.

5. The amplifier circuit of claim 1,
wherein the current path of the feed-forward circuit includes a controllable current source coupled to the output of the output stage,
wherein the controllable current source is activated when the differential input voltage crosses the threshold value.

6. The amplifier circuit of claim 1,
wherein the output stage includes a source follower.

7. The amplifier circuit of claim 6,
wherein the source follower comprises an n-channel field effect transistor, and
wherein the feed-forward circuit is configured to sink the additional output current when the differential input voltage falls below the threshold value.

8. The amplifier circuit of claim 6,
wherein the source follower comprises a p-channel field effect transistor, and
wherein the feed-forward circuit is configured to source the additional output current when the differential input voltage exceeds the threshold value.

9. A method comprising:
providing, by an input stage of an amplifier, an output signal that represents a differential input voltage of the input stage;
providing, by an output stage of the amplifier, an output voltage based on the output signal of the input stage at an amplifier output, wherein a feed-back path couples the amplifier output with an inverting input of the input stage; and
activating a current path coupled to the amplifier output to provide an additional output current when the differential input voltage crosses a threshold value.

10. A current sense amplifier comprising:
a first input node and a second input node configured to sense a voltage drop across a current sense resistor;
an input stage including an inverting input, which is coupled to the first input node via a first resistor, and a non-inverting input, which is coupled to the second input node via a second resistor, wherein the input stage is configured to provide an output signal that represents a differential input voltage received at the inverting input and the non-inverting input;
an output stage that includes a source follower configured to receive, as input signal, the output signal of the input stage and further configured to provide, at an amplifier output, an output voltage based on the input signal;
a feed-back path that couples the output of the output stage with the inverting input of the input stage; and
a feed-forward circuit is configured to activate a current path coupled to the output to provide an additional output current when the differential input voltage crosses a threshold value.
